(19) United States
(12) Patent Application Publication
(10) Pub. No.: US 2015/0001649 A1
(43) Pub. Date: Jan. 1, 2015

(54) MEMS Apparatus On a Lid With Flexible Substrate

(71) Applicant: Brandon Harrington, Chicago, IL (US)

(72) Inventor: Brandon Harrington, Chicago, IL (US)

(21) Appl. No.: 14/490,144

(22) Filed: Sep. 18, 2014

(51) Int. Cl. B81B 7/00

(52) U.S. Cl. CPC B81B 7/007; B81B 2201/0257; B81B 2203/0127
USPC 257/416

(57) ABSTRACT

A micro electro mechanical system (MEMS) assembly includes a flexible substrate and a lid having an underside. The lid has a port extending there through, and the lid is coupled to the port. A MEMS motor is attached to the underside of the lid and communicates with the port.

### TECHNICAL FIELD

This application relates to Microelectromechanical system (MEMS) assemblies and, more specifically, to their construction.

### BACKGROUND OF THE INVENTION

Microelectromechanical system (MEMS) devices include MEMS microphones. In the case of a MEMS microphone, sound energy enters through a sound port and vibrates a diaphragm and this action creates a corresponding change in electrical potential (voltage) between the diaphragm and a back plate disposed near the diaphragm. This voltage represents the sound energy that has been received. Typically, the voltage is then transmitted to an electric circuit (e.g., an integrated circuit such as an application specific integrated circuit (ASIC)). Further processing of the signal may be performed on the electrical circuit. For instance, amplification or filtering functions may be performed on the voltage signal at the integrated circuit.

The MEMS microphone includes a MEMS motor. The MEMS motor typically includes the diaphragm, the back plate and a MEMS die. In some cases, the motor is disposed on a base and the base is a printed circuit board (PCB) base. In other cases, the base is a ceramic base. In either of these cases, the disposal of the MEMS components on the base of the apparatus requires an apparatus that is often high in profile because the base of the apparatus together with the other components makes the profile high.

Today's electronics devices typically require components of the smallest size possible. Smaller devices (if they are to be made) would typically require even smaller components. The configuration of previous MEMS devices have limited the amount of possible height reduction for MEMS microphones resulting in limits as to how far the sizes of devices can be reduced. This, in turn, has resulted in some dissatisfaction with these previous approaches.

### BRIEF DESCRIPTION OF THE DRAWINGS

For a more complete understanding of the disclosure, reference should be made to the following detailed description and accompanying drawings wherein:

FIG. 1 comprises an exploded perspective view of a MEMS device and cover according to various embodiments of the present invention;

FIG. 2 comprises perspective bottom view of the partial microphone according to various embodiments of the present invention;

FIG. 3 comprises a top perspective view of the partial microphone according to various embodiments of the present invention;

FIG. 4 comprises a top view of the microphone on a substrate according to various embodiments of the present invention;

FIG. 5 comprises a cross-sectional view along line B-B of FIG. 4 according to various embodiments of the present invention;

FIG. 6 comprises a perspective top view of an array of microphones according to various embodiments of the present invention;

FIG. 7 comprises a side detail view A of the microphone array of FIG. 6 according to various embodiments of the present invention; and

FIG. 8 comprises a flow chart showing a manufacturing process for making a MEMS microphone with a flexible substrate according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Approaches are described that provide a MEMS motor disposed on the lid of a MEMS assembly and where a flexible substrate is provided. The approaches are easy and cost effective to implement. In addition, the resultant structure is smaller in dimensions (e.g., smaller in height) than that provided by previous approaches.

In one of these embodiments, a MEMS assembly includes a lid with an underside to which a MEMS motor is attached. The lid has a port or opening extending there through. The MEMS motor includes a MEMS die, a diaphragm, and a back plate. One or more walls form a cavity. The lid is coupled to the walls such that the MEMS motor is disposed within the cavity. The walls are adapted to be attached to a flexible substrate (e.g., a flexible printed circuit board (PCB)) by an appropriate fastening approach.

In another of these embodiments, a MEMS assembly includes a lid with an underside to which a MEMS motor is attached. The lid has a port or opening extending there through. The MEMS motor includes a MEMS die, a diaphragm, and a back plate. One or more walls form a cavity. The lid is coupled to the walls such that the MEMS motor is disposed within the cavity. A flexible substrate such as a flexible printed circuit board (PCB) is attached to the walls.

In still others of these embodiments, a manufacturing approach attaches a MEMS motor to a lid. The lid has a port or opening extending there through. The MEMS motor includes a MEMS die, a diaphragm, and a back plate. The lid is attached to walls that form a cavity. The lid is coupled to the walls such that the MEMS motor is disposed within the cavity. The walls are attached to a flexible substrate (e.g., a flexible printed circuit board (PCB)).

In yet others of these embodiments, a plurality of MEMS structures are disposed to a flexible printed circuit board (PCB). Each of the MEMS structures includes a lid with an underside to which a MEMS motor is attached. The lid has a port or opening extending there through. The MEMS motor includes a MEMS die, a diaphragm, and a back plate. One or more walls form a cavity. The lid is coupled to the walls such that the MEMS motor is disposed within the cavity. The walls are adapted to be attached to a flexible substrate such as a flexible printed circuit board (PCB).

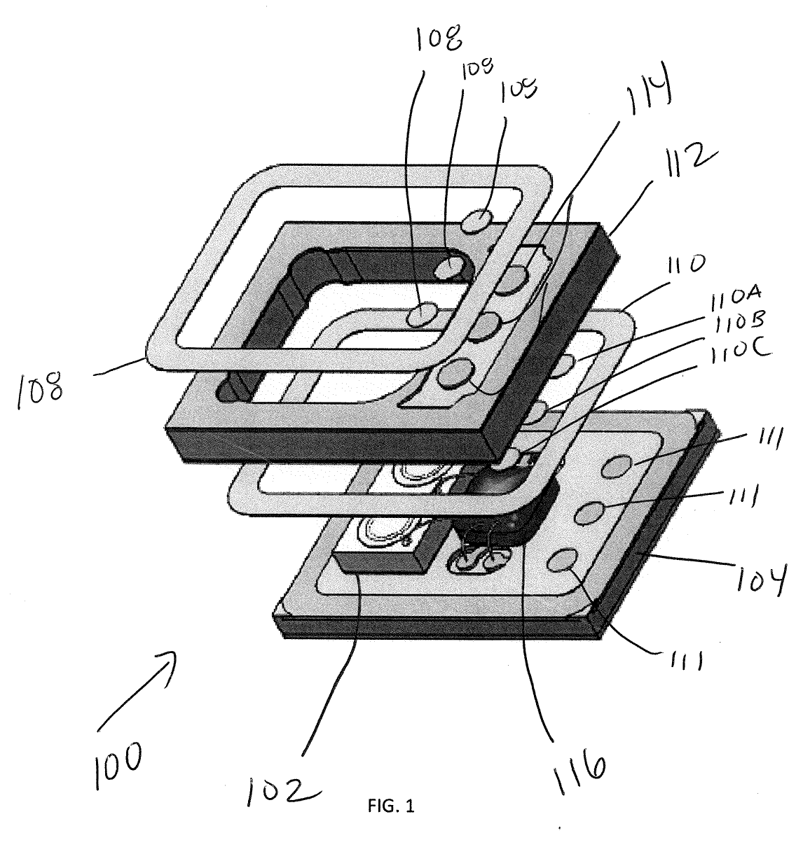

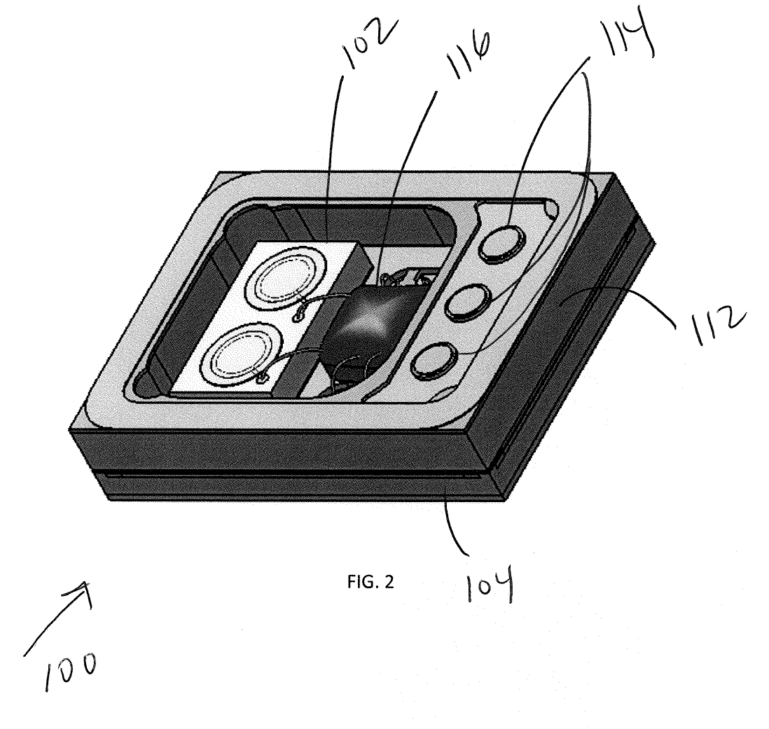

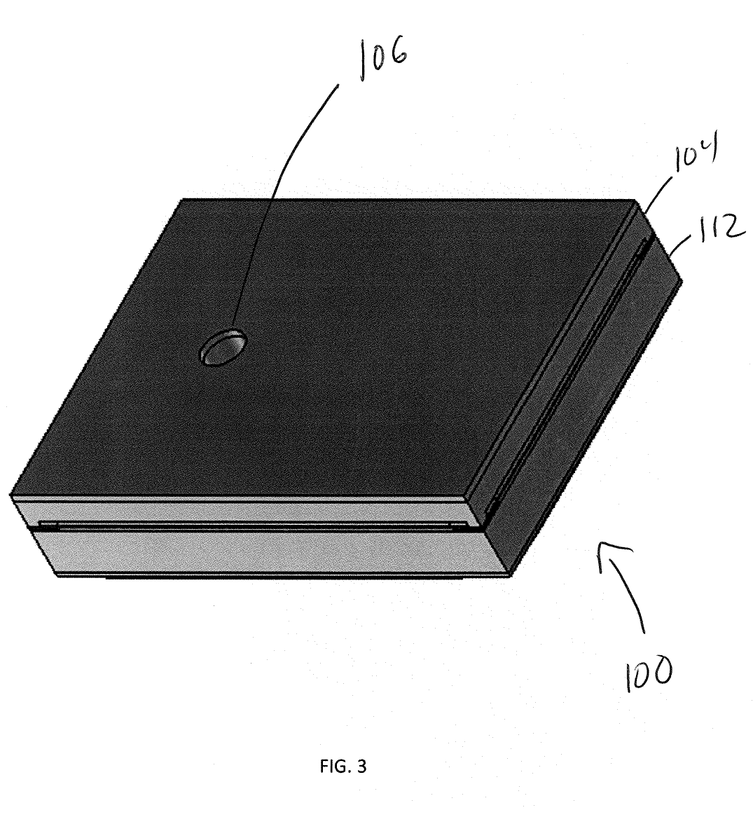

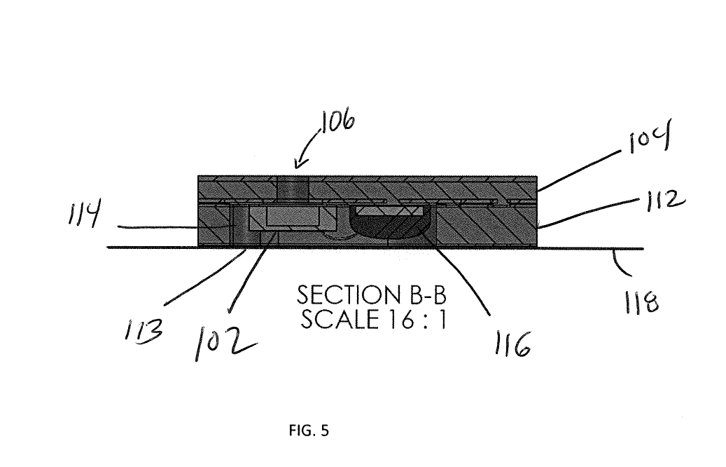

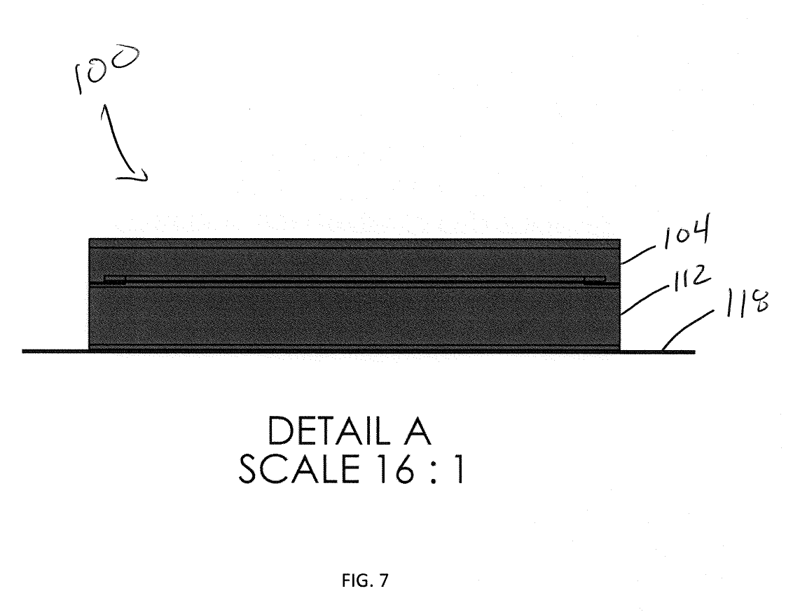

Referring now to FIGS. 1-7, a microphone assembly 100 includes a MEMS device or motor 102 (this includes a back plate, and a diaphragm, and a MEMS die), a cover 104, a port 106, a first solder layer 108, a second solder layer 110, walls 112, vias 114 in the walls 112, and an integrated circuit 116. These elements are disposed on a flexible substrate 118.

The lid or cover 104 may be constructed of any suitable material such as FR-4 PCB, ceramic, or plastic. As well as covering and enclosing components of the microphone assembly 100, the lid 104 provides electrical passageways (e.g., conductors or traces) that conduct electrical energy between the integrated circuit 116 and the conduits 114. The lid 104 also forms a cavity in which the MEMS motor 102 is disposed.

The port 106 extends through the lid 104. The function of the port 106 is to allow sound energy to reach the MEMS motor 102.

The MEMS motor 102 includes a diaphragm, a back plate, and a MEMS die. Sound energy enters through the sound port 106 and vibrates the diaphragm and this action creates a corresponding change in electrical potential (voltage) between the diaphragm and the back plate disposed near the diaphragm. This voltage represents the sound energy that has been received. In one example, there may be dual microphone elements with each of the microphone elements including a separate diaphragm and back plate.

The first solder layer 108 (including solder pads 108A, 108B, and 108C) and the second solder layer 110 (including solder pads 110A, 110B, and 110C) couple different components together. The first solder layer 108 couples the walls 112 to the flexible substrate 118. The second solder layer 110 couples the walls to the lid 104. The first solder layer 108 and the second solder layer 110 are electrically conductive and as described herein allow the conduction of electrical signals between the MEMS device 102 and the exterior of the microphone assembly 100.

The walls 112 are constructed, in some examples, of FR-4 PCB, ceramic, or plastic, and are disposed between the lid 104 and the flexible substrate 118. The walls 112 are adapted and configured to be attached to the flexible substrate 118. By “flexible substrate” and as used herein, it is meant a substrate that is composed at least in part of a flexible and pliable material. It will also be appreciated that a one-piece cover (that incorporates both the walls and a top lid) can also be used in place of a separate lid and walls described herein.

The vias 114 in the walls 112 are hollow extended openings or passageways (e.g., a hollow tube) that provide a conductive electrical passage way and provide an electrical connection between the lid 104 and the substrate 118. The vias 114 may be a filled with a metal or the vias 114 may be left open and are coated with a conductive metal. In any case, the vias 114 provide the needed electrical connection between the lid 104 and the substrate 118.

The integrated circuit 116 may be any type of processing device such as an application specific integrated circuit (ASIC). In one example, the integrated circuit 116 provides signal amplification functions. Other functions may be provided as well. The integrated circuit 116 is coupled to and receives signals from the MEMS motor 102. The signals from the MEMS device 102 are representative of sound received via the port 106.

The flexible substrate 118 is any type of thin, flexible, and pliable substrate such as a flexible printed circuit board (PCB). In one aspect, the flexible substrate is constructed of a first layer of insulation material such as polyester, polyimide, polyethylene napthalate, polyetherimide, polyether ether ketone, a patterned layer of copper (or other metal), and a second layer of insulation material such as polyester, polyimide, polyethylene napthalate, polyetherimide, polyether ether ketone. Other examples of insulation materials and metals are possible. In one aspect, the flexible substrate is less than approximately 100 microns thick.

When the walls 112 are connected to the flexible substrate 118, conventional techniques are used to remove portions of the first and second insulation layers to expose the copper layer. On a first side of the flexible substrate, the vias 114 in the walls 112 can be aligned with the exposed copper and the two elements coupled together, for example, using soldering approaches. On the second side of the substrate 118, soldering pads, or other attachments may be made that allow for external electrical connections to be made with the MEMS motor 102 and the integrated circuit 116.

In one example of the operation of the systems described with respect to FIGS. 1-7, sound energy enters through the sound port 106 and vibrates a diaphragm in the MEMS motor 102. This action creates a corresponding change in electrical potential (voltage) between the diaphragm and a back plate disposed near the diaphragm at the MEMS motor 102. This voltage represents the sound energy that has been received.

The voltage is then transmitted to the integrated circuit 116, for example by wires. For instance, amplification or filtering functions may be performed on the voltage signal at the integrated circuit 116. The integrated circuit 116 sends a signal via wires to the lid 104 where the electrical signal is transmitted via conductors (not shown) in the lid 104.

The conductors in the lid are coupled to conductive pads 111 via solder pads 110A, 110B, and 110C. The solder pads 110A, 110B, and 110C couple to the conduits 114 and consequently the electrical signal is transmitted through the conduits 114. The conduits 114 couple to solder pads 108A, 108B, and 108C. The solder pads 108A, 108B, and 108C, couple to a conductor 113 in the substrate 118. External devices can be coupled to the conductor 113 (via, for example, another conductive pad) or directly to the conductor 113.

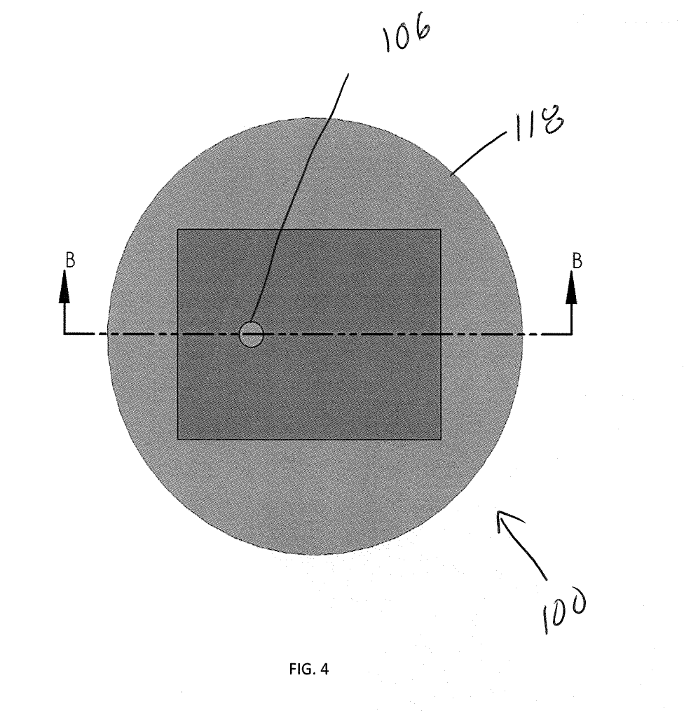

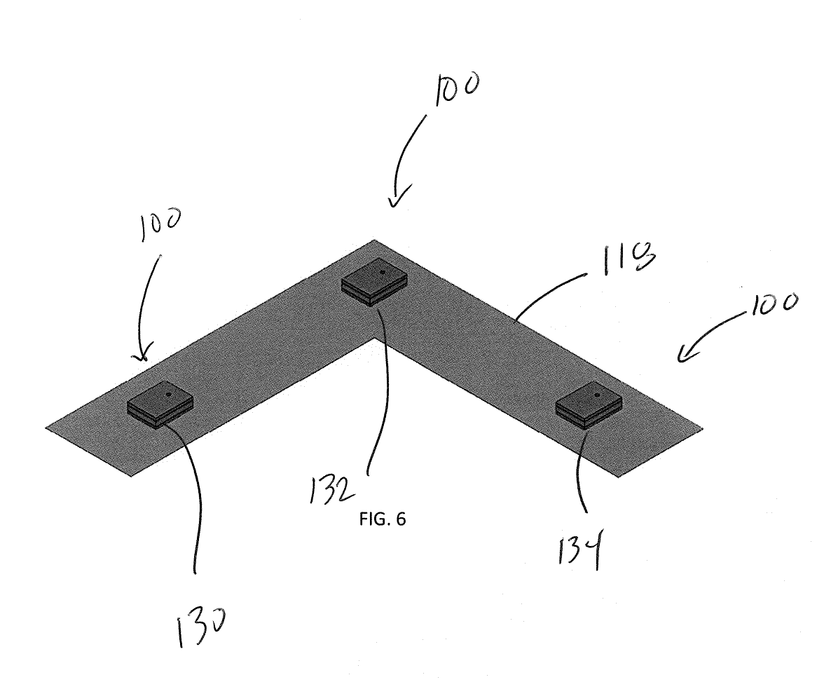

Referring now especially to FIGS. 4 and 6, it can be seen that a system or array of MEMS devices can be formed and created. This system can be constructed, for example, by disposing multiple MEMS devices 130, 132, and 134 on a flexible substrate 118. It will be appreciated that each of the MEMS devices 130, 132, and 134 can be constructed according to the principles described above with respect to the devices of FIGS. 1-6. Disposing an array of devices on the same substrate 118 allows for the easy manufacturing of multiple devices. In these regards, after disposing the individual devices 130, 132, and 134 on the substrate 118, the individual devices can be removed by cutting the substrate 118 to form individual devices.

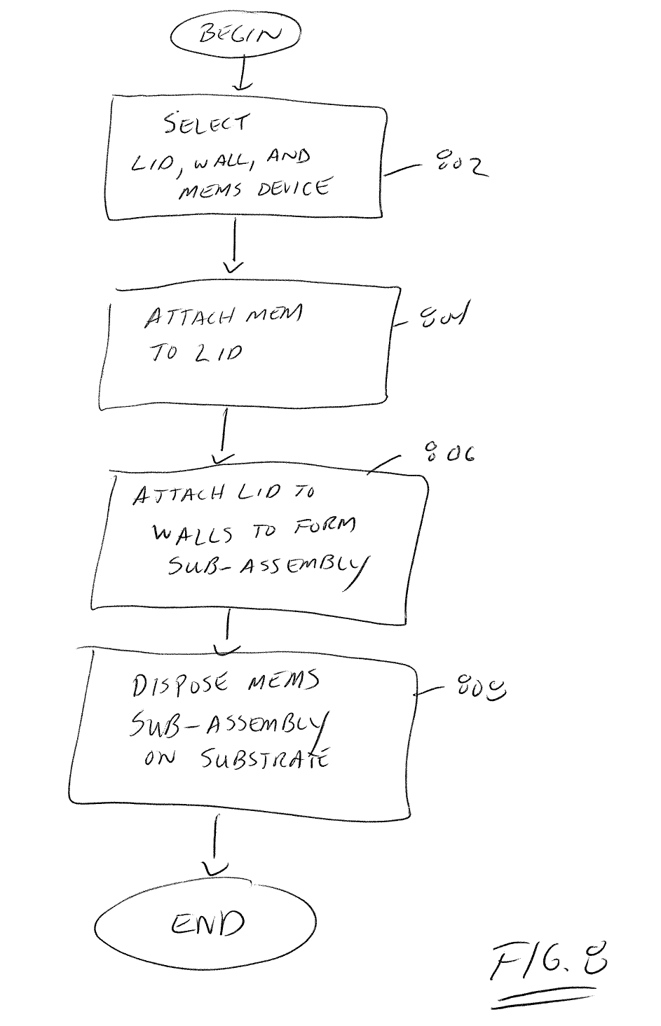

Referring now to FIGS. 8, one example of a process for manufacturing an MEMS microphone with a flexible substrate is described. At step 802, a lid, walls, and a MEMS die (with diaphragm and back plate) are obtained. These may be obtained from any suitable commercial source.

At step 804, the MEMS motor (the diaphragm, the back plate) are attached to an underside of the lid. The lid has a port and the MEMS motor is attached so that this apparatus is disposed over the port. The attachment may be made by glue or by any other appropriate attachment mechanism.

At step 806, the lid is attached to the wall to form a sub-assembly that now includes the cover, MEMS motor, and walls. At step 808, the sub-assembly is disposed on the flexible substrate. It will be appreciated that multiple sub-assemblies can be disposed on a single substrate during the manufacturing process. Attachment may be made by soldering it to the substrate.

Further, after each sub-assembly is disposed on and secured to the flexible substrate, each now-complete microphone assembly can be separated from the others by any appropriate approach.

Consequently, a MEMS microphone having a top port is provided that has a reduced height compared to previous examples. In the present cases, the height of the microphone can be approximately 850 microns. This compares to a height of approximately 1000 microns for previous MEMS microphones. Because the height of the MEMS microphone is reduced, the resultant part can fit into smaller spaces and the devices where the MEMS microphone is deployed can be reduced in size.

Further, arrays of MEMS microphones can be created where multiple sub-assemblies (each including a lid and MEMS motor) can be disposed on a flexible substrate such as a flexible PCB.

Additionally, a stiffener may be applied under the MEMS device. For example, additional metal layers (or layers of other stiffening materials) may be used to selectively stiffened but only in the region of the substrate under the microphone (or in some other area).

It will be appreciated that any type of MEMS motors can be used with the present approaches. Also, any type of routing of signals may be used from the top of the apparatus to the substrate.

Preferred embodiments of this invention are described herein, including the best mode known to the inventors for carrying out the invention. It should be understood that the illustrated embodiments are exemplary only, and should not be taken as limiting the scope of the invention.

What is claimed:

1. A micro electro mechanical system (MEMS) assembly, comprising:
a flexible substrate;
a lid having an underside, the lid having a port extending there through, the lid being coupled to the port;
a MEMS motor attached to the underside of the lid and communicating with the port.
